(19) United States
(12) Patent Application Publication
(10) Pub. No.: US 2009/0008136 A1
(43) Pub. Date: Jan. 8, 2009

(54) Multilayered printed circuit board and fabricating method thereof

(75) Inventors: Nobuyuki Ikeguchi, Suwon-si (KR); Keungjin Sohn, Seoul (KR); Joon-Sik Shin, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/213,868

(22) Filed: Jun. 25, 2008

(30) Foreign Application Priority Data
Jul. 4, 2007 (KR) 10-2007-0066896
Aug. 24, 2007 (KR) 10-2007-0085773

(51) Int. Cl. H05K 1/03; H05K 3/02

(52) U.S. Cl. 174/255; 29/843

(57) ABSTRACT

A multilayered printed circuit board and a method of fabricating the printed circuit board are disclosed. The method of fabricating the multilayered printed circuit board can include: providing a core substrate, which has an outer circuit, and which has a thermal expansion coefficient of 10 to 20 ppm/° C. at −60 to 150° C.; stacking a stress-relieving insulation layer, which has a thermal expansion coefficient of −20 to 6 ppm/° C., on either side of the core substrate; and forming a metal layer on the insulation layer and forming at least one pad and electrically connecting the pad with the outer circuit. This method can provide high reliability, as the stress-relieving insulation layers can prevent bending and warpage, etc., in the board overall.

### CROSS-REFERENCE TO RELATED APPLICATIONS

This application claims the benefit of Korean Patent Application No. 10-2007-0066896 and Korean Patent Application No. 10-2007-0085773 filed with the Korean Intellectual Property Office on Jul. 4, 2007, and Aug. 24, 2007, respectively, the disclosures of which are incorporated herein by reference in their entirety.

### BACKGROUND

1. Technical Field

The present invention relates to a multilayered printed circuit board and a method of fabricating the multilayered printed circuit board.

2. Description of the Related Art

Current electronic devices are trending towards smaller, thinner, and lighter products. In step with these trends, the preferred methods for mounting semiconductor chips are changing from wire bonding methods to flip chip methods, which entail greater numbers of terminals. In accordance with the use of flip chip methods for mounting semiconductor chips, there is a demand also for multilayered printed circuit boards that provide higher reliability and higher densities.

In the conventional multilayered printed circuit board, if glass fiber woven fabric is used for the base material, E glass fibers are generally used for the glass component. A thermosetting resin composition is impregnated into the glass fiber woven fabric and dried to a B-stage, after which a copper clad laminate is used to fabricate a core circuit board for the inner layer. Then, build-up sheets of B-stage thermosetting resin composition are stacked on either sides of the core circuit board to fabricate a multilayered printed circuit board.

In the multilayered printed circuit board thus fabricated, a build-up resin composition is used which has a high rate of thermal expansion (generally about 18 to 100 ppm/° C. in the longitudinal and lateral directions), and a solder resist is used on the surface layer which has an even higher rate of thermal expansion (generally about 50 to 150). Consequently, the overall coefficient of thermal expansion in the longitudinal and lateral directions for the multilayered printed circuit board is 13 to 30 ppm/° C. This coefficient of thermal expansion, however, is relatively high compared to that of the semiconductor chip, which ranges about 2 to 3 ppm/° C.

When there is a difference in coefficients of thermal expansion as such between the semiconductor chip and the multilayered printed circuit board on which the semiconductor chip is mounted, there is a risk of defects, such as cracking, peeling, etc. at the interface between the chip and the board, and damaging of the semiconductor chip. In cases where a semiconductor chip is mounted on only one side of a multilayered printed circuit board, there may be problems of the printed circuit board being bent or warped.

### SUMMARY

An aspect of the invention is to provide a multilayered printed circuit board and a method of fabricating the printed circuit board, in which there is high contact reliability between the semiconductor chip and the circuit board.

Another aspect of the invention provides a method of fabricating a multilayered printed circuit board that includes: providing a core substrate, which has an outer circuit, and which has a thermal expansion coefficient of 10 to 20 ppm/° C. at −60 to 150° C.; stacking a stress-relieving insulation layer, which has a thermal expansion coefficient of −20 to 6 ppm/° C., on either side of the core substrate; and forming a metal layer on the insulation layer and forming at least one pad and electrically connecting the pad with the outer circuit.

Embodiments of the invention for the method of fabricating a multilayered printed circuit board may include one or more of the following features. For example, the thermal expansion coefficient of the stress-relieving insulation layer can be −15 to 5 ppm/° C., and the metal layer can include copper. Also, a solder resist can be filled in between the remaining metal layer and the pad.

The stress-relieving insulation layer can include a reinforcing material, where the reinforcing material may include any one of T(S) glass fiber woven fabric, aromatic polyamide fiber non-woven fabric, aromatic polyamide fiber woven fabric, and liquid crystal polyester resin sheet. The stress-relieving insulation layer can be a thermosetting resin composition that includes the aromatic polyamide fiber non-woven fabric or the aromatic polyamide fiber woven fabric as the reinforcing material.

The stress-relieving insulation layer can be a thermosetting resin composition that includes the T(S) glass fiber woven fabric included as the reinforcing material. The stress-relieving insulation layer can be formed from a liquid crystal polyester resin composition that has a melting point of 270° C. or higher, and a solder ball can be formed on the pad that that may be connected with a semiconductor chip.

Still another aspect of the invention provides a multilayered printed circuit board that includes: a core substrate, which has an outer circuit, and which has a thermal expansion coefficient of 10 to 20 ppm/° C. at −60 to 150° C.; a stress-relieving insulation layer, which is formed on either side of the core substrate, and which has a thermal expansion coefficient of −20 to 6 ppm/° C.; and a pad formed on the stress-relieving insulation layer and electrically connected with the outer circuit.

Embodiments of the invention for the multilayered printed circuit board may include one or more of the following features. For example, the thermal expansion coefficient of the stress-relieving insulation layer can be −15 to 5 ppm/° C., and the metal layer can include copper. Also, the pad can be insulated by a solder resist.

The stress-relieving insulation layer can include a reinforcing material, where the reinforcing material may include any one of T(S) glass fiber woven fabric, aromatic polyamide fiber non-woven fabric, aromatic polyamide fiber woven fabric, and liquid crystal polyester resin sheet. The stress-relieving insulation layer can be a thermosetting resin composition that may include aromatic polyamide fiber non-woven fabric or aromatic polyamide fiber woven fabric as the reinforcing material, or can be a thermosetting resin composition including T(S) glass fiber woven fabric as the reinforcing material.

The stress-relieving insulation layer can be formed from a liquid crystal polyester resin composition having a melting point of 270° C. or higher, and a solder ball can be formed on the pad that is to be connected with a semiconductor chip.

Yet another aspect of the invention provides a method of fabricating a multilayered printed circuit board that includes: providing a core substrate, which has an outer circuit, and which has a thermal expansion coefficient of 10 to 20 ppm/° C. at −60 to 150° C.; stacking a metal layer, which has a thermal expansion coefficient of −5 to 8 ppm/° C., on either side of the core substrate; and forming at least one pad by removing at least one portion of the metal layer and electrically connecting the pad with the outer circuit of the core substrate.

Embodiments of the invention for the method of fabricating a multilayered printed circuit board may include one or more of the following features. For example, the thermal expansion coefficient of the metal layer can be −3 to 5 ppm/° C. In the removing of the metal layer, a remaining percentage of the metal layer can be 50% or higher, while an insulating material can be filled in between the remaining metal layer and the pad.

The metal layer may contain Invar, and a copper foil may be attached to the metal layer. The metal layer can be stacked with an interposed intermediate insulation layer after forming minute roughness on one side of the metal layer, or the metal layer can be stacked after applying a black oxide treatment or a CZ treatment to the copper foil. At least one solder ball may be formed over the pad that is connected with a semiconductor chip.

Still another aspect of the invention provides a multilayered printed circuit board that includes: a core substrate, which has an outer circuit, and which has a thermal expansion coefficient of 10 to 20 ppm/° C. at −60 to 150° C.; a metal layer stacked over either side of the core substrate that has a thermal expansion coefficient of −5 to 8 ppm/° C.; and a pad, which is electrically connected with the outer circuit, and which is formed by removing at least one portion of the metal layer.

Embodiments of the invention for the multilayered printed circuit board may include one or more of the following features. For example, the thermal expansion coefficient of the metal layer can be −3 to 5 ppm/° C., and the remaining percentage of the metal layer can be 50% or higher. An insulating material can be filled in between the remaining metal layer and the pad.

The metal layer may contain Invar, and a copper foil may be attached to the metal layer. Minute roughness can be formed on one side of the metal layer, and minute roughness can be formed on the copper foil by applying a black oxide treatment or a CZ treatment. At least one solder ball may be formed over the pad that is connected with a semiconductor chip.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of fabricating a multilayered printed circuit board according to an embodiment of the invention.

FIG. 2 is a cross-sectional view illustrating a stress-relieving insulation layer and a metal layer positioned on either side of a core substrate, in a method of fabricating a multilayered printed circuit board according to an embodiment of the invention.

FIG. 3 is a cross-sectional view illustrating pads formed after stacking the stress-relieving insulation layer and the metal layer, in a method of fabricating a multilayered printed circuit board according to an embodiment of the invention.

FIG. 4 is a cross-sectional view illustrating a multilayered printed circuit board according to an embodiment of the invention, with chips mounted on.

FIG. 5 is a flowchart illustrating a method of fabricating a multilayered printed circuit board according to another embodiment of the invention.

FIG. 6 is a cross-sectional view illustrating an intermediate insulation layer and a metal layer positioned on either side of a core substrate, in a method of fabricating a multilayered printed circuit board according to another embodiment of the invention.

FIG. 7 is a cross-sectional view after stacking the intermediate insulation layer and the metal layer onto either side of the core substrate of FIG. 6.

FIG. 8 is a cross-sectional view illustrating the multilayered printed circuit board of FIG. 7, with through-holes and pads formed.

FIG. 9 is a plan view after removing portions of the first metal layer to form pads.

FIG. 10 and FIG. 11 are cross-sectional views of a multilayered printed circuit board according to yet another embodiment of the invention, with chips mounted on.

### DETAILED DESCRIPTION

The multilayered printed circuit board and fabricating method thereof according to certain embodiments of the invention will be described below in more detail with reference to the accompanying drawings. Those elements that are the same or are in correspondence are rendered the same reference numeral regardless of the figure number, and redundant explanations are omitted.

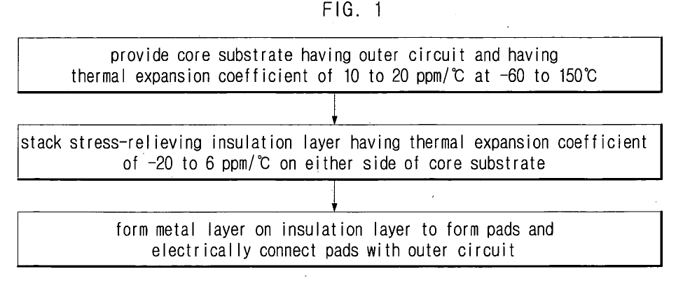

FIG. 1 is a flowchart illustrating a method of fabricating a multilayered printed circuit board according to an embodiment of the invention.

Referring to FIG. 1, a method of fabricating a multilayered printed circuit board according to an embodiment of the invention may include providing a core substrate, which has an outer circuit, and which has a thermal expansion coefficient of 10 to 20 ppm/° C. at −60 to 150° C.; stacking a stress-relieving insulation layer, which has a thermal expansion coefficient of −20 to 6 ppm/° C., on either side of the core substrate; and stacking a metal layer, forming at least one pad, and electrically connecting the pad with the outer circuit.

A feature in the method of fabricating a multilayered printed circuit board according to this particular embodiment is that stress-relieving insulation layers, which have a coefficient of thermal expansion lower than that of the core substrate, may be stacked on both sides of the core substrate, to prevent the bending and warping of the overall printed circuit board. A semiconductor chip can be mounted on a multilayered printed circuit board thus fabricated, using a method known to those skilled in the art, such as those that utilize common solder balls, lead-free solder balls, or gold solder balls, etc.

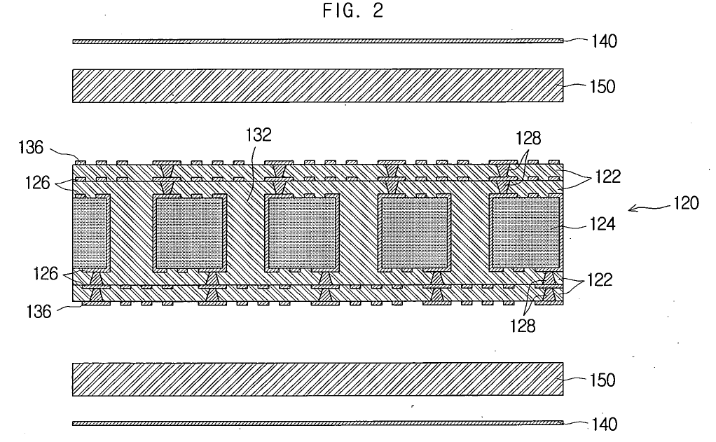

A method of fabricating a multilayered printed circuit board according to an embodiment of the invention will be described below in more detail with reference to FIG. 2 to FIG. 4.

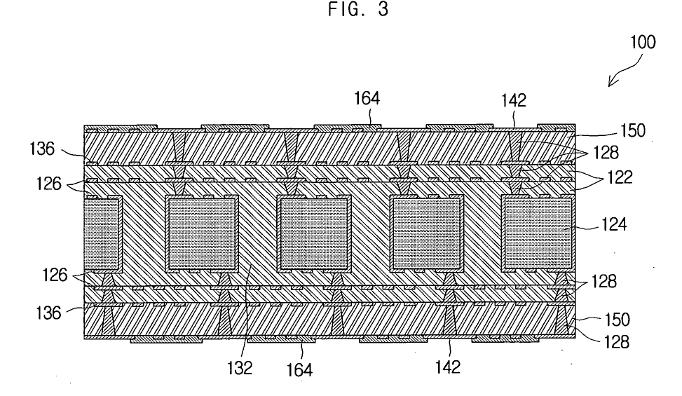

FIG. 2 is a cross-sectional view illustrating a stress-relieving insulation layer 150 and a metal layer 140 positioned in order on either side of a core substrate 120, and FIG. 3 is a cross-sectional view illustrating the stress-relieving insulation layer 150 and the metal layer 140 stacked on.

Referring to FIG. 2, the stress-relieving insulation layer 150 and the metal layer 140 may be sequentially positioned-on either side of the core substrate 120. The core substrate 120 may generally have a rate of thermal expansion of 10 to 20 ppm/° C. at −60 to 150° C. The thermal expansion coefficient of the stress-relieving insulation layer 150 may be −20 to 6 ppm/° C. As such, since the coefficient of thermal expansion of the stress-relieving insulation layers 150 may be lower than that of the core substrate 120, the stress-relieving insulation layers 150 may prevent the core substrate 120 from bending or warpage, and may thus provide high overall reliability even after mounting semiconductor chips on.

Inner circuits 126 and build-up insulation layers 122 may be formed in order on either side of a core insulation layer 124 in the core substrate 120, while outer circuits 136 may be formed on the outermost layers. An equal number of build-up insulation layers 122 may be stacked on the outer sides of either side of the core insulation layer 124. Also, a build-up resin composition or IVH ink can be filled in between portions of the core insulation layer 124.

A typical multilayered printed circuit board can be used for the core substrate 120. For example, a circuit board of an epoxy resin composition, polyimide resin composition, cyanate ester resin composition, cyanate ester maleimide resin composition, benzocyclobutene resin composition, polyphenylene ether resin composition, or functional-group-containing polyphenylene ether resin composition can be used, although the invention is not thus limited. Among the above examples, the epoxy resin and cyanate ester resin compositions may offer the advantage of relatively low cost.

In general, a double-sided copper clad laminate used for the core substrate 120 can utilize non-woven or woven fabric of inorganic or organic fibers as reinforcing material. Examples of inorganic fibers include E, D (S), NE glass fibers, etc. Also, examples of organic fibers include heat-resistant fibers such as poly-oxybenzol fibers, aromatic polyamide fibers, and liquid crystal polyester fibers, etc. Polyimide film, aromatic polyamide film, and liquid crystal polyester film, etc., can also be used for the reinforcing material. In order to improve the adhesion between the reinforcing material and the resin, a surface treatment known to those skilled in the art may be applied to the reinforcing material. Examples include silane coupling agent treatment for inorganic material such as glass fiber fabric, etc., and plasma treatment, corona treatment, various chemical treatments, and blast treatment, etc., for organic material such as film, etc., which can be applied selectively. In the case of film material, a copper clad sheet can be used, in which a copper foil can be attached to either side of the film by applying adhesive or by directly attaching the copper foils according to a method known to those skilled in the art.

The build-up insulation layer 122 can be formed from a generally known thermosetting resin, thermoplastic resin, UV-setting resin, unsaturated-group-containing resin, etc., or from a combination of two or more of such resins. In certain cases, a thermosetting resin composition can be used, or a heat-resistant thermoplastic resin composition having a melting point of 270° C. or higher can be used.

The thermosetting resin used for the insulation layer of the core substrate 120 can be such that is generally known to those skilled in the art. For example, epoxy resin, cyanate ester resin, bismaleimide resin, polyimide resin, functional-group-containing polyphenylene ether resin, cardo resin, or phenol resin, etc., as a resin known to those skilled in the art, can be used by itself or in a combination of two or more resins. In certain cases, cyanate ester resin may be used to prevent migration between gradually narrowing through-holes or between circuits. The known resins described above may be used after applying flame-retardant treatment with phosphorus.

While a thermosetting resin according to this embodiment can be hardened by heating the resin as is, this may entail a slow hardening rate and low productivity. Thus, an adequate amount of hardening agent or thermosetting catalyst may be used in the thermosetting resin.

Various other additives may generally be used in the thermosetting resin. For example, a thermosetting resin, a thermoplastic resin, or another type of resin may be added, other than the main resin used, as well as adequate amounts of an organic or inorganic filler, a dye, pigments, a thickening agent, lubricant, an antifoaming agent, a dispersing agent, leveling agent, brightening agent, and thixotropic agent, etc., according to the purpose and usage of the composition. It is also possible to use a flame retardant, such as those using phosphorus and bromine, and non-halogenated types.

The thermoplastic resin used can be such that is generally known to those skilled in the art. More specifically, liquid crystal polyester resin, polyurethane resin, polyamide resin, polyphenylene ether resin, etc. can be used by itself or in a combination of two or more resins. The thermoplastic that is used can have a melting point of 270° C. or higher, so that there may be no defects in the wiring board during the reflow treatment process, which is performed under high temperatures. The various additives described above may also be added in adequate amounts to the thermoplastic resin. Furthermore, a thermoplastic resin and a thermosetting resin can be used together as a mixture.

Besides the thermosetting resin and thermoplastic resin, other resins may be used alone or in combination, such as UV-setting resins and rapid setting resins, etc. Also, a photopolymerization initiator, radical polymerization initiator, and/or the various additives described above can be mixed in to adequate amounts.

Fabricating the core substrate 120 does not necessarily have to include only the same resin compositions as those described above. For example, a copper clad laminate having an E glass fiber woven fabric base and an epoxy resin composition may be used for the core insulation layer 124, while a sheet of a B stage cyanate ester resin composition that does not have a reinforcing material but with a copper foil added, or a sheet of B stage unsaturated-group-containing polyphenylene ether resin, etc., may be used for a build-up insulation layer 122.

The core substrate 120 can be a multilayered printed circuit board generally fabricated by a method known to those skilled in the art, for which a relatively inexpensive material may be used, such as a copper clad laminate having an E glass fiber woven fabric base and an epoxy resin composition, or an E glass fiber woven fabric base cyanate ester resin composition, and prepreg, etc. Here, in cases where the core substrate 120 is to have a low coefficient of thermal expansion, aromatic polyamide fiber or T(S) glass fiber woven fabric, which are relatively more expensive, may be used, by itself or in combination in the copper clad laminate or prepreg, etc., to obtain a coefficient of thermal expansion close to 10 ppm/° C.

The method for fabricating the core substrate 120 is not particularly limited, and conventional subtractive and semi-additive methods, etc., may be used. While the coefficient of thermal expansion of the core substrate 120 may be measured by a known method, such as the method used for TMA, etc., when reinforcing material or different resins are used, the coefficient of thermal expansion may be used to express a composite of the coefficients of thermal expansion of the various materials.

The stress-relieving insulation layer 150 according to this embodiment may have a coefficient of thermal expansion in the range of −20 to 6 ppm/° C. In certain cases, the stress-relieving insulation layer 150 may have a coefficient of thermal expansion of −15 to 5 ppm/° C. The stress-relieving insulation layer 150 need not be limited to particular materials, and can be made from any of the resins used for forming the build-up insulation layer 122.

The stress-relieving insulation layer 150 according to this embodiment may include a reinforcing material. Examples of possible reinforcing materials include T(S) glass fiber woven fabric, aromatic polyamide fiber non-woven fabric, aromatic polyamide fiber woven fabric, and liquid crystal polyester resin sheet (This may be used for both the reinforcing and the resin in an integrated manner.). The stress-relieving insulation layer 150 may be stacked on either side of the core substrate 120, and the thickness, of the stress-relieving insulation layer 150 can be selected in correspondence to the coefficient of thermal expansion of the core substrate 120.

FIG. 3 is a cross-sectional view illustrating pads 142 formed after stacking the stress-relieving insulation layer 150 and the metal layer 140 on either side of the core substrate 120.

Referring to FIG. 3, the stress-relieving insulation layers 150 and the metal layers 140 can be stacked on both outer layers of the core substrate 120 to form an integrated body. Here, minute depressions and mounds can be formed in the core substrate 120 by chemical etching or sandblasting, etc., and in some cases, chemical treatment may be applied. After etching the metal layers 140, via holes 128 may be formed by drilling and plating, and then pads 142 may be formed that electrically connect to the outer circuits 136. A solder resist 164 may be filled in between the each of the pads 142.

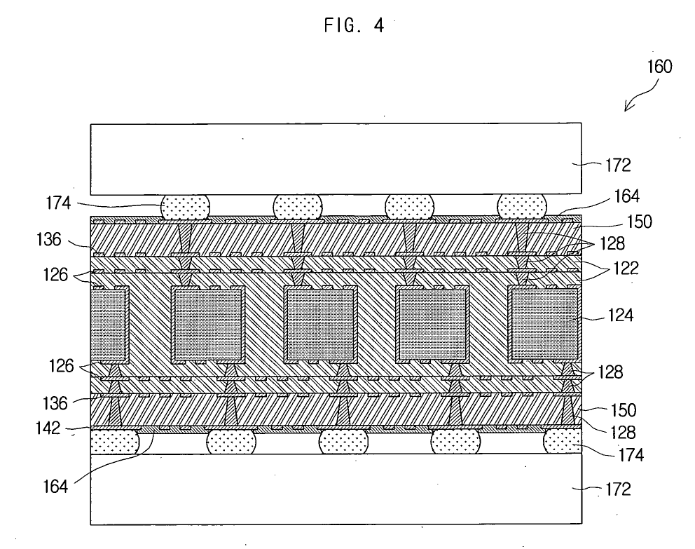

FIG. 4 is a cross-sectional view illustrating a multilayered printed circuit board 100 with semiconductor chips 172 mounted on by a flip chip method to form a flip chip package 160.

Referring to FIG. 4, solder balls 174 may be formed on the pads 142. The shape of the pads 142 may generally be circular, but it is to be appreciated that the shape may vary according tot the pads for connecting to the semiconductor chips. The solder balls 174 may be connected with a semiconductor chip 172. A metal layer may be formed on a pad 142, which can be made of a material high in electrical conductivity, such as gold, etc. While FIG. 4 illustrates a semiconductor chip 172 mounted on either side of the multilayered printed circuit board 100, various circumstances may have the semiconductor chip 172 on one side only.

Also, while the multilayered printed circuit board 100 according to this embodiment is illustrated as having the semiconductor chips mounted on by a flip chip method, the semiconductor chips may just as well be mounted by other methods, such as wire bonding. Furthermore, when mounting semiconductor chip on one side only, solder balls may be attached to the opposite side for connecting to a main board, whereby a ball grid array package may be formed.

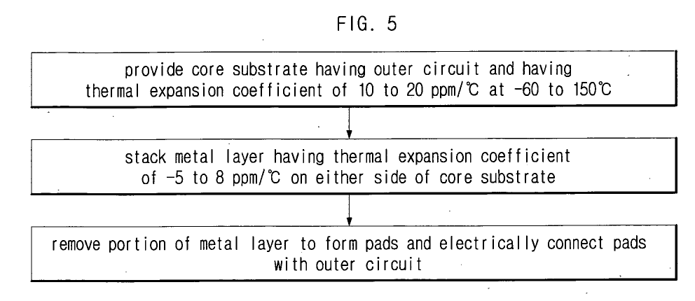

FIG. 5 is a flowchart illustrating a method of fabricating a multilayered printed circuit board according to an embodiment of the invention.

Referring to FIG. 5, a method of fabricating a multilayered printed circuit board according to an embodiment of the invention can include providing a core substrate that includes outer circuits and has a coefficient of thermal expansion of 10 to 20 ppm/° C. at −60 to 150° C., stacking metal layers having a coefficient of thermal expansion of −5 to 8 ppm/° C. on both outer sides of the core substrate, and removing portions of the metal layers to form pads and electrically connecting the pads with the outer circuits.

With the method of fabricating a multilayered printed circuit board according to this embodiment, a metal layer having a relatively lower coefficient of thermal expansion than that of the core substrate may be stacked over either side of the core substrate, so that bending and warpage may be prevented overall in the printed circuit board when flip chips are mounted installed and connected to the multilayered printed circuit board. Semiconductor chips can be mounted on the pads of a multilayered printed circuit board thus manufactured, using methods known to those skilled in the art, such as methods that use regular solder balls, lead-free solder balls, and gold solder balls, etc. A semiconductor plastic package made by connecting flip chips with lead-free solder may provide higher reliability in temperature cycle experiments, etc., with a reduced occurrence of cracking and peeling in the solder.

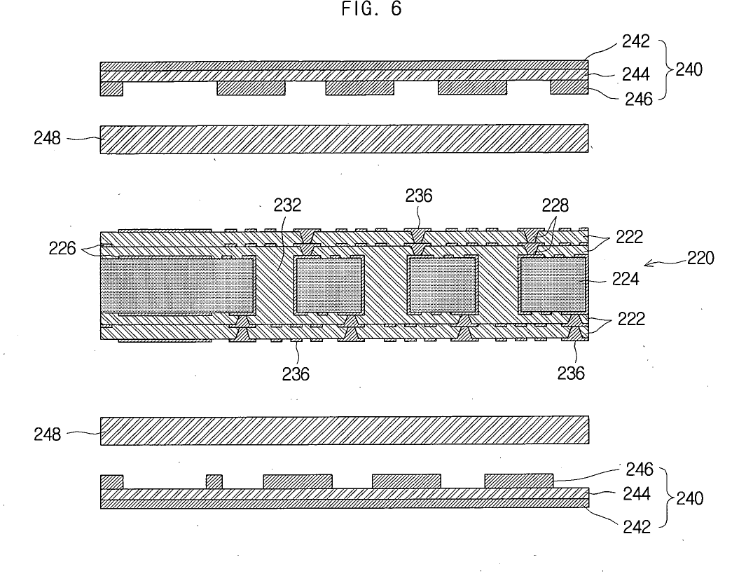

A method of manufacturing a multilayered printed circuit board according to an embodiment of the invention will be described below in more detail with reference to FIGS. 6 to 10.

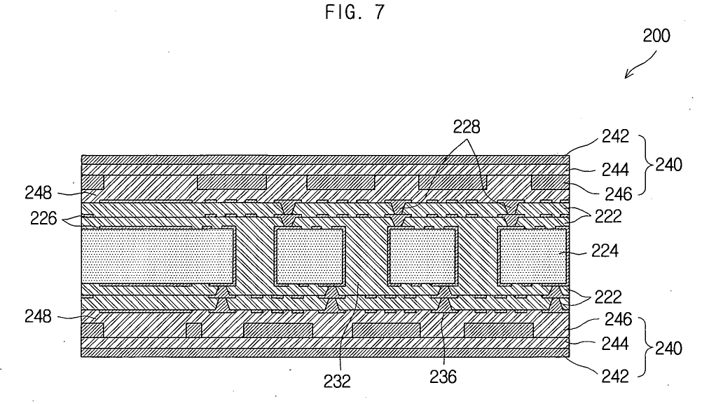

FIG. 6 is a cross-sectional view illustrating an intermediate insulation layer 248 and a metal layer 240 positioned in order on either side of a core substrate 220, and FIG. 7 is a cross-sectional view after stacking the intermediate insulation layers 248 and the metal layers 240 in FIG. 6.

Referring to FIG. 6, an intermediate insulation layer and a metal layer 240 can be stacked sequentially on either outer side of the core substrate 220. The core substrate 220 may generally have a rate of thermal expansion of 10 to 20 ppm/° C. at −60 to 150° C. The thermal expansion coefficient of the metal layer 240 may be −5 to 8 ppm/° C. As such, since the coefficient of thermal expansion of the metal layers 240 may be lower than that of the core substrate 220, the metal layers 240 may prevent thermal expansion in the core substrate 220 and reduce the overall coefficient of thermal expansion to a value similar to the thermal expansion coefficients of the semiconductor chips. Then, by using metals that also have a coefficient of thermal expansion similar to those of the semiconductor chips for the bumps connecting the flip chips, the stresses between the semiconductor chips and the bumps during the connecting of the flip chips in the reflow process can be decreased, to prevent bending and warpage in the multilayered printed circuit board. This can also provide a generally higher reliability even after the semiconductor chips are mounted on.

Inner circuits 226 and build-up insulation layers 222 may be formed in order on either side of a core insulation layer 224 in the core substrate 220, while outer circuits 236 may be formed on the outermost layers. An equal number of build-up insulation layers 222 may be stacked on the outer sides of either side of the core insulation layer 224. Also, a build-up resin composition or IVH ink can be filled in between portions of the core insulation layer 224.

The copper clad laminate and build-up insulation layers 222 can be formed from a generally known thermosetting resin, thermoplastic resin, UV-setting resin, unsaturated-group-containing resin, etc., or from a combination of two or more of such resins. In certain cases, a thermosetting resin composition can be used, or a heat-resistant thermoplastic resin composition having a melting point of 270° C. or higher can be used.

The metal layer 240 can be positioned as an outermost layer, and can include a first metal layer 242 made of Invar, a second metal layer 246 made of Invar having portions etched for forming blind via holes, and an insulation layer 144 interposed between the first metal layer 242 and the second metal layer 246.

The first metal layer 242 and the second metal layer 246 used in this embodiment can be made from alloys such as Invar and copper-Invar, etc., but are not limited to particular materials. Invar is an alloy of iron (Fe) and nickel (Ni), and has a coefficient of thermal expansion of 1 ppm/° C. or lower at a temperature of 200° C. or lower. Small amounts of cobalt (Co), manganese (Mn), niobium (Nb), aluminum nitride (AlN), etc., can be added to the Invar. The material can be used after aging.

Copper-Invar can be a material having a three-layer structure, in which copper layers of 1 to 200 μm thickness may be attached by rolling onto both sides of a layer of Invar. Of course, the copper layers can be attached by sputtering, etc., to provide copper layers of 1 μm or lower. Because copper has a high coefficient of thermal expansion, of about 17 ppm/° C., the integrated copper-Invar material can have very thin layers of copper, so that the overall coefficient of thermal expansion does not exceed 8 ppm/° C. If the copper layers are thick, the copper layers on both sides can be etched to a thickness of 5 μm or lower. It is also possible to use a copper-Invar layer in which a copper layer is attached to only one side. Other metals such as nickel can be used instead of the copper.

The coefficient of thermal expansion, thickness, and number of copper layers of the metal layer 240 can be selected in consideration of the coefficient of thermal expansion of the core substrate 220. Of course, it is possible to fabricate the core substrate 220 from a metal material having a low coefficient of thermal expansion structured to have three or more layers. To obtain a desired coefficient of thermal expansion from the metal layer 240 with a small number of layers, the remaining percentage of the metal layer 240 can be increased in the subsequent process. This will be described below in more detail.

Referring to FIG. 7, metal layers 240 may be stacked over both outer layers, using intermediate insulation layers 248 such as prepreg, etc. Here, minute roughness can be formed in the core substrate 220, using chemical etching or sandblasting, etc., and chemical treatment can be applied as necessary.

In the case of copper-Invar, after etching the copper foils on the surface layers to a thickness of 1 to 3 μm, a black oxide treatment or a CZ treatment (as supplied by Meck K. K.), etc., can be applied to the copper foils, and intermediate insulation layers 248, such as prepreg, etc., can be stack-molded. A thick layer of copper remaining can lead to a high coefficient of thermal expansion. Of course, a general treatment can be performed on the copper foils for increasing adhesion to the resin composition.

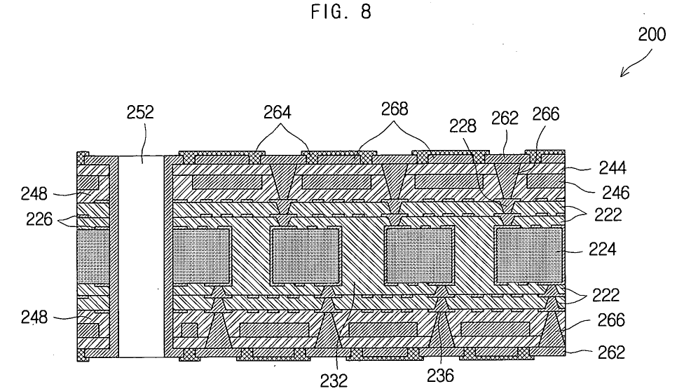

A method of processing the copper-Invar or Invar to form via holes can employ, for example, a UV-YAG laser, a diamond drill, or etching, or combinations thereof. Also, an etchant such as ferric chloride, etc., can be used in forming the circuits. Using such methods, portions of the second metal layer 246 can be removed-to provide space for forming via holes 266 (see FIG. 8) that connect the pads 262 (see FIG. 8) on the outer layers and the outer circuits 236 of the core substrate.

FIG. 8 is a cross-sectional view after stacking the metal layers 240 and forming pads 262 on the first metal layer 242 and via holes 266 that connect the pads 262 with the outer circuits 236 of the core substrate.

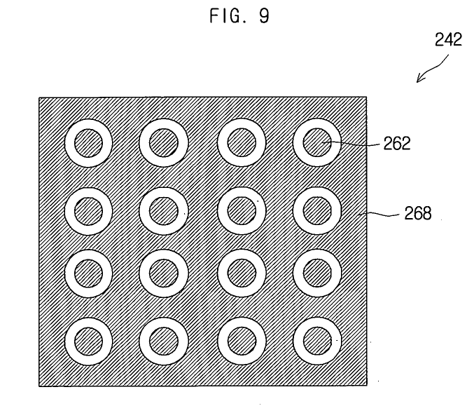

Referring to FIG. 8, portions of the first metal layer 242 can be removed to form pads 262. Solder resists 264 can be formed between the pads 262 and the remaining metal portions 268 for insulation, while the pads 262 and the outer circuits 236 of the core substrate can be connected by via holes 266. In a subsequent process, solder balls 274 (see FIG. 9) can be formed over the pads 262. Also, through-holes 252 can be formed as necessary in the multilayered printed circuit board 200.

FIG. 9 illustrates pads 262 and remaining metal portions 268 formed by removing portions of the first metal layer 242.

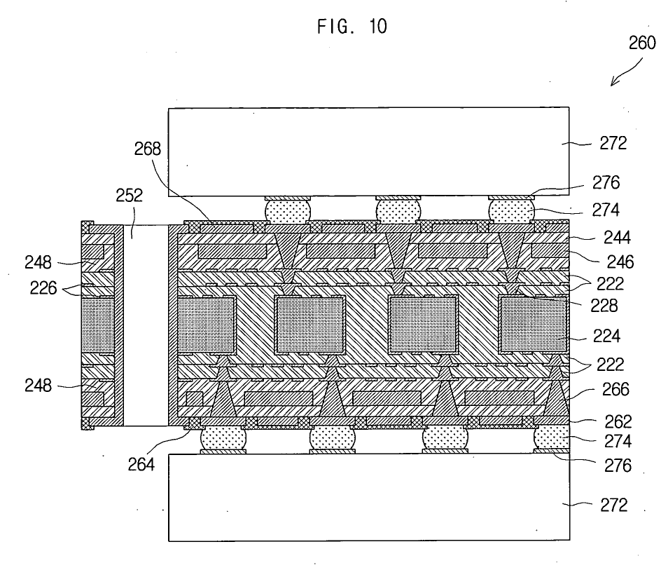

Solder balls 274 (FIG. 10) can be formed over the pads 262. While the shape of the pads 262 may generally be circular, it is apparent that the shape may vary according to the type of connection pads of the semiconductor chip. Also, as described above, the areas of the pads 262 and the remaining metal portions 268 can be made to be about 50% or higher of the original area of the first metal layers 242, so as not to provide an excessively high coefficient of thermal expansion increase in the metal layers.

FIG. 10 is a cross-sectional view in which semiconductor chips 272 have been mounted on a multilayered printed circuit board 200 according to an embodiment of the invention to form a flip chip package 260.

Referring to FIG. 10, solder balls 274 can be formed over the pads 262 of the multilayered printed circuit board 200. The solder balls 274 can be connected with the connection pads 276 of the semiconductor chips 272. A metal layer having high electrical conductivity, such as gold, etc., may also be formed over the pads 262. While FIG. 10 illustrates the case where semiconductor chips 272 are mounted on both sides of the multilayered printed circuit board 200, in certain cases, a semiconductor chip 272 can be mounted on just one side as necessary.

Also, while the semiconductor chips may be mounted on a multilayered printed circuit board 200 according to this embodiment using a flip chip method, it is also possible to mount the semiconductor chips using wire bonding. Furthermore, in cases where a semiconductor chip is mounted only one side, solder balls for connecting to a main board can be attached to the opposite side, whereby a ball grid array package can be formed.

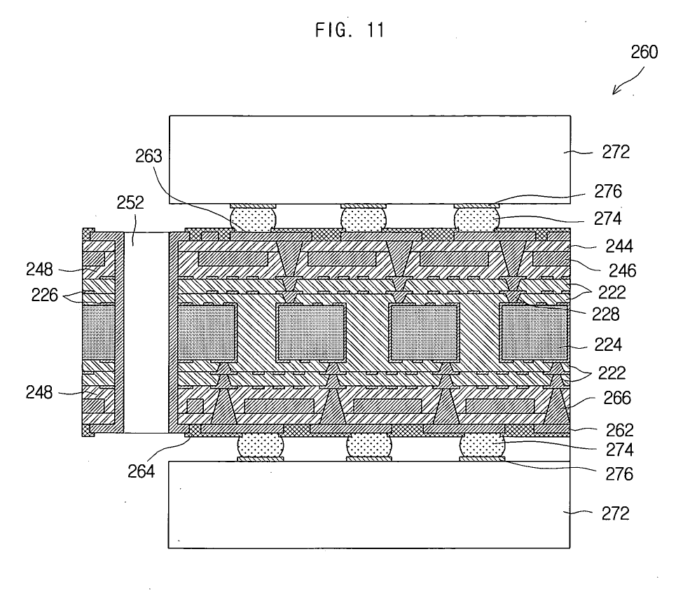

FIG. 11 is a cross-sectional view illustrating semiconductor chips 272 mounted on a multilayered printed circuit board 200 according to an embodiment of the invention to form a flip chip package 260, where solder balls 274 are formed over portions 163 extended from the pads 262.

As illustrated in FIG. 11, the solder balls 274 can be formed in portions 163 extended from the pads 262, away from the portions of the via holes 266. In this way, the positioning of the solder balls 274 may be performed with greater ease.

### EXAMPLES

The compositions and features of certain embodiments of the invention will be described below in greater detail by evaluating implementation examples based on embodiments of the invention and other comparison examples. Here, “parts” refer to parts by weight, unless otherwise specified.

### Implementation Example 1

(1) Fabrication of Core Substrate

To a copper clad laminate (product name: ELC-4785 GS, CTEα1: 11 ppm/° C., Sumitomo Bakelite Co., Ltd.) having a 12 μm-thick electro-deposited copper layer attached on either side of a 0.2 mm-thick insulation layer of epoxy, the copper of the surface layers were etched to a thickness of 1.3 μm. Then, through-holes were formed using a metal drill to an inner diameter of 150 μm, and desmearing was performed, after which an electroless plating copper layer of 0.9 μm and an electroplating copper layer of 20 μm were applied. Afterwards, circuits were formed by a subtractive method to a ratio of line/space=40/40 μm, and black copper oxide treatment was performed. Then, a build-up sheet (product name: APL-3601, Sumitomo Bakelite Co., Ltd.) of 40 μm thickness was applied on either side, a 12 μm-thick electro-deposited copper layer was arranged on either outer side, and stack-molding was performed for 90 minutes in a 200° C., 25 kgf/cm², and 2 mmHg vacuum, to fabricate a four-layer double-sided copper clad stack.

Then, the surface layers of the electro-deposited copper were etched to 1.8 μm, and blind via holes of a 50 μm diameter were formed using UV-YAG laser, after which a desmearing treatment was performed. Afterwards, the insides of the holes were filled with copper plating, and outer circuits were fabricated on the surfaces. These procedures were repeated to fabricate PCB-A (core substrate), which has six layers. Also, a CZ treatment (supplied by Meck K. K.) was performed on the surfaces of PCB-A, to form PCB-B having six layers. The rate of thermal expansion was shown to be 17.8 ppm/° C. in the regions of PCB-A where semiconductor chips were installed.

(2) Fabrication of Multilayered PCB Stacked with Stress-Relieving Insulation Layers

Liquid crystal polyester resin composition sheets (product name: FA film, coefficient of thermal expansion: −13 ppm/° C., melting point: 280° C.) were positioned on both sides respectively of the six-layer PCB-B, and then 12 μm-thick electro-deposited copper was positioned on the outer sides, which were stacked for 20 minutes in a 290° C., 15 kgf/cm², and 2 mmHg vacuum and subsequently cooled, to form an eight-layer copper clad stack. Then, the layers of copper on the surfaces were etched to 1.2 μm, blind via holes of a 70 μm diameter were formed on both sides using UV-YAG laser, and then a desmearing treatment was performed with plasma, after which the insides of the via holes were filled with copper plating. In addition, pads with a pitch of 400 μm were formed on the surfaces for connecting semiconductor chips, where the diameter of the pads were 180 μm, and solder resists (product name: PSR4000AUS308, Taiyo Ink Mfg. Co., Ltd.) were formed on the surfaces to a thickness of 15 μm, after which nickel plating to 5 μm and gold plating to 0.2 μm were performed to fabricate an integrated eight-layer PCB-C.

(3) Fabrication of Flip Chip Package

Semiconductor chips having lead-free solder (Sn-3.5Ag, melting temperature 221 to 223° C.) attached were positioned on either side of PCB-C and were attached by reflowing in a temperature of up to 260° C., to fabricate a flip chip package. Using the flip chip thus formed, temperature cycle experiments were performed for a −45° C./30 min←→125° C./30 min cycle for 1000 cycles, the evaluation results of which are listed in Table 1.

### Implementation Example 2

(1) Fabrication of Core Substrate

2,2-Bis(4-cyanatophenyl)propane monomers of 550 parts were dissolved at 160° C. and were reacted while being stirred for 4.5 hours, to yield a mixture of monomers and prepolymers. These were dissolved in methyl ethyl ketone and mixed with 100 parts of bisphenol A epoxy resin (product name: Epikote 1001, Japan Epoxy Resins Co., Ltd.), 150 parts of phenol novolac epoxy resin (product name: DEN-431, Dow Chemical Company), and 200 parts of cresol novolac epoxy resin (product name: ESCN-220 F, Sumitomo Chemical Co., Ltd.), after which 0.2 parts of zinc octylate was dissolved as a hardening catalyst in the methyl ethyl ketone. The mixture was mixed and stirred to form Varnish-D. Then, 1000 parts of spherical silica (average particle diameter: 0.9 μm) inorganic filler was added, stirred, and dispersed to form Varnish-E.

Varnish-D was impregnated into a 200 μm-thick aramid fiber woven fabric and dried, to fabricate Prepreg-F having a gelation time of 112 seconds (at 170° C.) and a resin content of 43 weight %.

Then, using one sheet of Prepreg-F, a 12 μm-thick layer of electro-deposited copper was positioned on either outer side, and stack-molding was performed for 90 minutes in a 190° C., 20 kgf/cm², and 2 mmHg vacuum, to fabricate a double-sided copper clad laminate of 0.2 mm thickness. After etching the copper on both sides of the double-sided copper clad laminate to 2 μm, through-holes of a 150 μm diameter were formed using UV-YAG laser, and then, after a desmearing treatment, an electroless plating copper layer of 0.9 μm and an electroplating copper layer of 20 μm were formed. Then, circuits were formed by a subtractive method to a ratio of line/space=40/40 μm. Also, after applying a CZ treatment (supplied by Meck K. K.) onto the copper layers, one sheet of prepreg (product name: APL-3601, Sumitomo Bakelite Co., Ltd.) of 40 μm thickness was arranged respectively on either side, and 12 μm-thick electro-deposited copper layers were arranged on the outer sides, which were stack-molded to fabricate a four-layer double-sided copper clad stack.

After etching the copper layers on the surfaces of the four-layer double-sided copper clad stack to a thickness of 1.3 μm, blind via holes of a 50 μm diameter were formed by irradiating UV-YAG laser. After a desmearing treatment, the insides of the holes were filled with copper plating. Next, outer circuits were formed on the surfaces, and the CZ treatment, stacking, and circuit-forming were repeated to fabricate PCB-I. A CZ treatment (supplied by Meck K. K.) was performed on the surfaces of PCB-I, to form a six-layer PCB-J, i.e. the core substrate. The rate of thermal expansion was shown to be 11.7 ppm/° C. in the regions of PCB-J where semiconductor chips were installed.

(2) Fabrication of Multilayered PCB

Varnish-E was impregnated into a 100 μm-thick aramid fiber woven fabric and dried, to fabricate Prepreg-K having a gelation time of 133 seconds (at 170° C.) and a resin content of 51 weight %.

One sheet of Prepreg-K (CTEα1 after hardening: 4.1 ppm/° C.) having an aramid fiber woven fabric base was arranged at each side of the six-layered PCB-J, and 12 μm-thick layers of electro-deposited copper were arranged on the outer sides, which were stack-molded for 90 minutes in a 190° C., 20 kgf/cm², 2 mmHg vacuum, to fabricate an eight-layer copper clad stack. After removing the copper layers on the surfaces to a thickness of 1.2 μm by etching, blind via holes of a 70 μm diameter were formed on both sides using UV-YAG laser, and a desmearing treatment was performed using plasma. Next, the insides of the via holes were filled with copper plating, and pads with a pitch of 400 μm were formed on the surfaces for connecting semiconductor chips, where the diameter of the pads were 180 μm, after which solder resists were formed on the surfaces to a thickness of 15 μm, and nickel plating to 5 μm and gold plating to 0.2 μm were performed to fabricate an eight-layer PCB-L.

(3) Fabrication of Flip Chip Package

Semiconductor chips having lead-free solder (Sn-3.5Ag, melting temperature 221 to 223° C.) attached were positioned on either side of PCB-L and were attached by reflowing in a temperature of up to 260° C., to fabricate a flip, chip package. Using the flip chip thus formed, temperature cycle experiments were performed for a −45° C./30 min←→125° C./30 min cycle for 1000 cycles, the evaluation results of which are listed in Table 1.

### Implementation Example 3

(1) Fabrication of Core Substrate

First, a core substrate was prepared by performing the processes described as in (1) of Implementation Example 2.

(2) Fabrication of Multilayered PCB

Varnish-E was impregnated into a 100 μm-thick T(S) glass fiber woven fabric and dried, to fabricate Prepreg-M having a gelation time of 117 seconds and a resin content of 55 weight %. Then, a sheet of T(S) glass fiber woven fabric Prepreg M (CTEα1 after hardening: 5.3 ppm/° C.) was placed each on both sides of PCB-J, and 12 μm-thick electro-deposited copper layers were arranged on the outer sides, which were stack-molded for 90 minutes in a 190° C., 40 kgf/cm², 2 mmHg vacuum, to fabricate an eight-layer copper clad stack. After removing the copper layers on the surfaces to a thickness of 1.5 μm by etching, blind via holes of a 70 μm diameter were formed on both sides using UV-YAG laser. Then, the blind via holes were subjected to a desmearing treatment using plasma, and the insides of the via holes were filled with copper plating. Connecting pads were formed on the surfaces that have a pitch of 400 μm, and a diameter of 180 μm, after which solder resists were formed on the surfaces to a thickness of 15 μm, and nickel plating to 5 μm and gold plating to 0.2 μm were performed to fabricate an eight-layer PCB-N.

(3) Fabrication of Flip Chip Package

Semiconductor chips having lead-free solder (Sn-3.5Ag, melting temperature 221 to 223° C.) attached were positioned on either side of PCB-L and were attached by reflowing in a temperature of up to 260° C., to fabricate a flip chip package. Using the flip chip thus formed, temperature cycle experiments were performed for a −45° C./30 min←→125° C./30 min cycle for 1000 cycles, the evaluation results of which are listed in Table 1.

### Implementation Example 4

The same experiments as for Implementation Examples 1 through 3 were performed for the eight-layer PCB-C from Implementation Example 1, but with semiconductor chips mounted only on one side, for which the evaluation results are listed in Table 1.

### Comparison Example 1

Onto the six-layer multilayered PCB-B from Implementation Example 1, one layer of prepreg (product name GEA-679 FGR, Hitachi Chemical Co. Ltd.) was positioned to a thickness of 40 μm on either side, after which one 12-μm layer of electro-deposited copper was arranged on each of the outer sides, which were stack-molded for 90 minutes in a 200° C., 25 kgf/cm², and 2 mmHg vacuum, to fabricate an eight-layer double-sided copper clad stack. Then, using the same method as that used for the above Implementation Examples, an eight-layer PCB-O was fabricated, and semiconductor chips were mounted on both sides. Evaluation results for this case are listed in Table 2.

### Comparison Example 2

Onto the six-layer PCB-J used in Implementation Examples 2 to 4, one layer of prepreg (product name APL-3651, Sumitomo Bakelite Co., Ltd.) was positioned with a thickness of 40 μm on either side. Then, one 12-μm layer of electro-deposited copper was arranged on each of the outer sides, which were stack-molded to fabricate an eight-layer PCB-P. Then, semiconductor chips were mounted on both sides. Evaluation results for this case are listed in Table 2.

### Comparison Example 3

For the eight-layer PCB-O fabricated in Comparison Example 1, semiconductor chips were mounted on only one side. Evaluation results for this case are listed in Table 2.

### Comparison Example 4

Onto the six-layer PCB-B used in Implementation Examples 2 to 4, one layer of aramid fiber woven fabric base prepreg, having a coefficient of thermal expansion of 8.8 ppm/° C. after hardening and a thickness of 105 μm, was arranged on either side. Then, one 12-μm layer of electro-deposited copper was arranged on each of the outer sides, which were stack-molded for 90 minutes in a 190° C., 25 kgf/cm ² and 2 mmHg vacuum, to fabricate an eight-layer double-sided copper clad stack. This was used to fabricate an eight-layer PCB-Q, using the same method as that used for the above Implementation Examples, after which semiconductor chips were mounted on one side only. Evaluation results for this case are listed in Table 2.

TABLE 1
Evaluation Results for Implementation Examples 1 to 4

| | Imple- | Imple- | Imple- | Imple- |
|---|---|---|---|---|
| | mentation | mentation | mentation | mentation |
| | Example 1 | Example 2 | Example 3 | Example 4 |
| Semiconductor Chip | Both Sides | Both Sides | Both Sides | One Side |
| Mounting | | | | |
| Solder Ball | Lead-Free Solder Balls | | | |
| Bending and | 88 | 73 | 69 | 165 |
| Warpage (μm) | | | | |
| Number of Products | 20 | 20 | 20 | 20 |
| Free from Cracking | | | | |
| and Peeling Defects | | | | |
| (n/20) | | | | |

TABLE 2
Evaluation Results for Comparison Examples 1 to 4

| | Com- | Com- | | |
|---|---|---|---|---|
| | parison | parison | Comparison | Comparison |
| | Example 1 | Example 2 | Example 3 | Example 4 |
| Semiconductor Chip | Both Sides | Both Sides | One Side | One Side |
| Mounting | | | | |
| Solder Ball | Lead-Free Solder Balls | | | |
| Bending and | 126 | 109 | 581 | 329 |
| Warpage (μm) | | | | |
| Number of Products | 2 | 6 | 0 | 12 |
| Free from Cracking | | | | |
| and Peeling Defects | | | | |
| (n/20) | | | | |

### Measurement Method

(1) Bending and Warpage

For twenty 40×100 mm modules, each having two flip chips of dimensions 10×10 mm and a thickness of 400 μm connected to the left, right, and middle (for a total of six chips) on one or both sides, the bending and warpage were measured using a laser measurement apparatus. The initial printed circuit boards selected displayed bending and warpage of 50±5 μm. The maximum values of bending and warpage were measured using a laser measurement apparatus after connecting the flip chips on.

(2) Cracking and Peeling Defects

For twenty 40×100 mm modules, each having two flip chips of dimensions 10×10 mm and a thickness of 400 μm connected to the left, right, and middle (for a total of six chips) on one or both sides, temperature cycle experiments were performed for a −45° C./30 min←→125° C./30 min cycle for 1000 cycles, and the integrity of the connection was evaluated. Here, a change in resistance value of ±15% or more was classified as a defect. The samples were checked for cracking and peeling in the lead-free solder balls, caused by cracking and peeling of the semiconductor chips.

Comparing Table 1 and Table 2, it can be observed that there were less bending and warpage, as well as fewer cases of cracking and peeling defects, in the multilayered printed circuit boards of the Implementation Examples according to certain embodiments of the invention than in the PCB's of the Comparison Examples. This may be because the stress-relieving insulation layers stacked on the multilayered printed circuit boards according to the embodiments of the invention prevent bending and warping in the board overall. Also, as can be seen in Tables 1 and 2, there are fewer cases of bending and warpage in the overall flip chip package for the cases of mounting semiconductor chips on both sides, compared to the cases of mounting the semiconductor chips on one side only.

### Implementation Example 5

(1) Fabrication of Core Substrate

To a copper clad laminate (product name: ELC-4785 GS, CTEα1: 11 ppm/° C., Sumitomo Bakelite Co., Ltd.) having a 12 μm-thick electro-deposited copper layer attached on either side of a 0.2 mm-thick insulation layer of epoxy, the copper of the surface layers were etched to a thickness of 1.8 μm. Then, through-holes were formed using a metal drill to an inner diameter of 150 μm, and desmearing was performed, after which an electroless plating copper layer of 0.9 μm and an electroplating copper layer of 20 μm were applied. Afterwards, circuits were formed by a subtractive method to a ratio of line/space=40/40 μm, and black copper oxide treatment was performed. Then, a build-up sheet (product name: APL-3601, Sumitomo Bakelite Co., Ltd.) of 40 μm thickness was applied on either side, a 12 μm-thick electro-deposited copper layer was arranged on either outer side, and stack-molding was performed for 90 minutes in a 200° C., 25 kgf/cm², and 2 mmHg vacuum, to fabricate a four-layer double-sided copper clad stack.

Then, the surface layers of the electro-deposited copper were etched to 2.0 μm, and blind via holes of a 50 μm diameter were formed using UV-YAG laser, after which a desmearing treatment was performed. Afterwards, the insides of the holes were filled with copper plating, and outer circuits were fabricated on the surfaces. These procedures were repeated to fabricate PCB-A′ (core substrate), which has six layers. Also, a CZ treatment (supplied by Meck K. K.) was performed on the surfaces of PCB-A′, to form PCB-B′ having six layers. The rate of thermal expansion was shown to be 17.8 ppm/° C. in the regions of PCB-A′ where semiconductor chips were installed.

(2) Fabrication of Multilayered PCB Stacked with Metal Layers

Minute surface roughness (R_{z}: 3.2 μm) was formed respectively on 20 μm and 50 μm-thick layers of Invar (Fe—Ni—Co alloy, coefficient of thermal expansion: 0.4 ppm/° C., Hitachi Metals, Ltd.), which were arranged on either side of a 30 μm-thick insulation layer (product name APL-3651, Sumitomo Bakelite Co., Ltd.) and then stack-molded for 90 minutes in a 200° C., 30 kgf/cm², and 2 mmHg vacuum. Then, a circuit was formed in the 50 μm-thick layer of Invar using a ferric chloride solution to form a metal layer-C′.

The metal layer-C′ thus formed was positioned on either side of the six-layer PCB-B′ with one 40 μm-thick intermediate insulation layer of APL-3651 placed in-between, to form a 10-layer copper clad stack-D′. A hole-forming auxiliary sheet (product name: LE400, Mitsubishi Gas Chemical Company, Inc.) was placed above the arrangement, while a 1.6 mm-thick paper phenol board placed below the arrangement, and through-holes were formed using a diamond drill having a diameter of 200 μm. Afterwards, the hole-forming auxiliary sheet above and below the arrangement were removed, and blind via holes of an 85 μm diameter were formed in each side using a UV-YAG laser. Then, a desmearing treatment was applied and a copper film was formed over each surface by sputtering to a thickness of 710 Å.

A copper foil was formed by electroless copper plating to a thickness of 0.9 μm, and the blind via holes were filled in using copper electroplating. Also, the copper layers plated on the surfaces were etched to a thickness of 1.3 μm to decrease the thickness of the copper layers. Then, connection lands having a diameter of 180 μm were formed on the surfaces in a pitch of 400 μm. The remaining percentage was kept as high as possible for the Invar portions in the outermost layers and the second outermost layers. Solder resists (product name: PSR4000AUS308, Taiyo Ink Mfg. Co., Ltd.) were formed on the surfaces to a thickness of 15 μm, after which nickel plating to 5 μm and gold plating to 0.2 μm were performed over portions where copper was exposed, including inside the through-holes, to fabricate a ten-layer PCB-E′.

Semiconductor chips were attached by reflowing in a temperature of up to 260° C. using lead-free solder balls (Sn-3.5Ag, melting temperature 221 to 223° C.).

Evaluation results from tests conducted with the flip chip package thus formed are listed below in Table 3.

### Implementation Example 6

(1) Fabrication of Core Substrate

2,2-Bis(4-cyanatophenyl)propane monomers of 550 parts were dissolved at 150° C. and were reacted while being stirred for 4.5 hours, to yield a mixture of monomers and prepolymers. These were dissolved in methyl ethyl ketone and mixed with 200 parts of bisphenol A epoxy resin (product name: Epikote 2001, Japan Epoxy Resins Co., Ltd.), 150 parts of phenol novolac epoxy resin (product name: DEN-431, Dow Chemical Company), and 200 parts of cresol novolac epoxy resin (product name: ESCN-220 F, Sumitomo Chemical Co., Ltd.), after which 0.2 parts of zinc octylate was dissolved as a hardening catalyst in the methyl ethyl ketone. The mixture was mixed and stirred to form Varnish-F′. Then, 2000 parts of spherical silica (average particle diameter: 0.9 μm) inorganic filler was added, stirred, and dispersed to form Varnish-G′.

Varnish-F′ was impregnated into a 200 μm-thick aramid fiber woven fabric and dried, to fabricate Prepreg-H′ having a gelation time of 112 seconds (at 170° C.) and a resin content of 43 weight %.

Also, Varnish-G′ was impregnated into a 50 μm-thick T(S) glass fiber woven fabric and dried, to fabricate Prepreg-I′ having a gelation time of 246 seconds (at 170° C.) and a resin content of 73 weight %.

Using one sheet of Prepreg-H′, a 12 μm-thick layer of electro-deposited copper was positioned on either outer side, and stack-molding was performed for 90 minutes in a 190° C., 20 kgf/cm², and 2 mmHg vacuum, to fabricate a double-sided copper clad laminate of 0.2 mm thickness. After etching the copper on both sides of the double-sided copper clad laminate to 1.4 μm, through-holes of a 150 μm diameter were formed using UV-YAG laser, and then, after a desmearing treatment, an electroless plating copper layer of 0.9 μm and an electroplating copper layer of 20 μm were formed. Then, circuits were formed by a subtractive method to a ratio of line/space=40/40 μm. Also, after applying a CZ treatment (supplied by Meck K. K.) onto the copper layers, one sheet of prepreg (product name: APL-3601, Sumitomo Bakelite Co., Ltd.) of 40 μm thickness was arranged respectively on either side, and 12 μm-thick electro-deposited copper layers were arranged on the outer sides, which were stack-molded to fabricate a four-layer double-sided copper clad stack.

After etching the copper layers on the surfaces of the four-layer double-sided copper clad stack to a thickness of 1.3 μm, blind via holes of a 50 μm diameter were formed by irradiating UV-YAG laser. After a desmearing treatment, the insides of the holes were filled with copper plating. Next, outer circuits were formed on the surfaces, and the CZ treatment, stacking, and circuit-forming were repeated to fabricate PCB-J′. A CZ treatment (supplied by Meck K. K.) was performed on the surfaces of PCB-J′, to form a six-layer PCB-K′, i.e. the core substrate. The rate of thermal expansion was shown to be 11.7 ppm/° C. in the regions of PCB-J′ where semiconductor chips were installed.

(2) Fabrication of Multilayered PCB

One sheet of Prepreg-I′ was arranged at each side of the six-layered PCB-K′, and copper-Invar plates (coefficient of thermal expansion: 4.0 ppm/° C.), each of which includes a 3 μm copper layer attached to either side of a 25 μm-thick layer of Invar, were arranged on the outer sides. These were stack-molded to fabricate an eight-layer copper clad stack-L′. Blind via holes of a 70 μm diameter were formed on both sides using UV-YAG laser, and a desmearing treatment was performed using plasma, after which the insides of the via holes were filled with copper plating. The copper layers plated over the surfaces were etched to a thickness of 1.2 μm to minimize thermal expansion. Pads were formed on the surfaces with a pitch of 400 μm and a diameter of 180 μm, to fabricate an integrated eight-layer printed circuit board. The remaining percentage was kept as high as possible for the copper-Invar portions, besides the circuit-forming portions, in each layer. Solder resists (product name: PSR4000AUS308, Taiyo Ink Mfg. Co., Ltd.) were formed on the surfaces to a thickness of 15 μm, after which nickel plating to 5 μm and gold plating to 0.2 μm were performed to fabricate an eight-layer PCB-M′.

Semiconductor chips were attached to both sides of the eight-layer PCB-M′ by reflowing in a temperature of up to 260° C. using lead-free solder (Sn-3.5Ag, melting temperature 221 to 223° C.), to form a flip chip package.

Evaluation results, from tests conducted with the flip chip package thus formed are listed below in Table 3.

### Implementation Examples 7 and 8

The same experiments as for Implementation Examples 5 and 6 were performed for the integrated ten-layer PCB-E′ and the eight-layer PCB-M′ from Implementation Examples 5 and 6, but with semiconductor chips mounted only on one side, respectively. The evaluation results are listed below in Table 3.

### Implementation Example 9

The eight-layer PCB-M′ was used with a reduced remaining percentage of the copper-Invar layers on the outermost layers, but with otherwise the same conditions, to fabricate an eight-layer PCB-N′. A semiconductor chip was mounted only on one side of PCB-N′. Evaluation results are listed below in Table 3.

### Comparison Example 5

Using the six-layer PCB-B′ from Implementation Example 5, one layer of prepreg (product name GEA-679 FGR, Hitachi Chemical Co. Ltd.) was positioned to a thickness of 40 μm on either side, after which one 12-μm layer of electro-deposited copper was arranged on each of the outer sides, which were stack-molded for 90 minutes in a 200° C., 25 kgf/cm², and 2 mmHg vacuum, to fabricate an eight-layer double-sided copper clad stack-O′. Then, blind via holes wee formed using the same method as that used for the above Implementation Example, and the-same method was repeated to fabricate a ten-layer PCB-P′. Semiconductor chips were mounted on both sides. Evaluation results for this case are listed in Table 4.

### Comparison Example 6

Onto the six-layer PCB-K′ used in Implementation Example 6, one layer of prepreg (product name APL-3651, Sumitomo Bakelite Co., Ltd.) was positioned with a thickness of 40 μm on either side. Then, one 12-μm layer of electro-deposited copper was arranged on each of the outer sides, which were stack-molded to fabricate an eight-layer PCB-Q′. Then, semiconductor chips were mounted on both sides. Evaluation results for this case are listed in Table 4.

### Comparison Examples 7 and 8

For the ten-layer PCB-P′ and the eight-layer PCB-Q′ fabricated in Comparison Examples 5 and 6, semiconductor chips were mounted on only one side, respectively. Evaluation results for this case are listed in Table 4.

### Comparison Example 9

Since copper layers were used in the outermost layers of Comparison Examples 5 to 8, the remaining percentage of copper was lowered to below 50%, because an increased remaining percentage of copper may increase the coefficient of thermal expansion of the integrated multilayered printed circuit board, and hence increase the difference in coefficient of thermal expansion with the semiconductor chip. In Comparison Example 9, the eight-layer PCB-Q′ was used with the remaining percentage of copper on the outermost layers increased to above 50%, but with otherwise the same conditions, to fabricate an eight-layer PCB-R′. A semiconductor chip was mounted only on one side of PCB-R′. Evaluation results are listed below in Table 4.

TABLE 3
Evaluation Results for Implementation Examples 5 to 9

| | | Implement. | Implement. | Implement. | Implement. | Implement. |
|---|---|---|---|---|---|---|
| | | Example 5 | Example 6 | Example 7 | Example 8 | Example 9 |
| Metal | Outermost | 67 | 82 | 67 | 82 | 45 |
| Remaining | Layer | | | | | |
| Percentage | Second | 85 | — | 85 | — | — |
| (%) | Outermost | | | | | |
| | Layer | | | | | |

| Semiconductor | Both Sides | Both Sides | Both Sides | One Side | One Side |
|---|---|---|---|---|---|
| Chip Mounting | | | | | |
| Solder Ball | Lead-Free Solder Balls | | | | |
| Bending and Warpage | 75 | 60 | 101 | 121 | 189 |
| (μm) | | | | | |
| Number of Products | 50 | 50 | 50 | 50 | 50 |
| Free from Cracking | | | | | |
| and Peeling Defects | | | | | |
| (n/50) | | | | | |

TABLE 4
Evaluation Results for Comparison Examples 5 to 9

| | | Compar. | Compar. | Compar. | Compar. | Compar. |
|---|---|---|---|---|---|---|
| | | Example 5 | Example 6 | Example 7 | Example 8 | Example 9 |
| Metal | Outermost | 40 | 49 | 40 | 49 | 82 |
| Remaining | Layer | | | | | |
| Percentage | Second | 85 | — | 85 | — | — |
| (%) | Outermost | | | | | |
| | Layer | | | | | |

| Semiconductor | Both Sides | Both Sides | Both Sides | One Side | One Side |
|---|---|---|---|---|---|
| Chip Mounting | | | | | |
| Solder Ball | Lead-Free Solder Balls | | | | |
| Bending and Warpage | 121 | 115 | 598 | 332 | 761 |
| (μm) | | | | | |
| Number of Products | 5 | 14 | 0 | 7 | 0 |
| Free from Cracking | | | | | |
| and Peeling Defects | | | | | |
| (n/50) | | | | | |

### Measurement Method

(1) Bending and Warpage

For fifty 40×200 mm modules, each having two flip chips of dimensions 10×10 mm and a thickness of 400 μm connected to the left, right, and middle (for a total of six chips) on one or both sides, the bending and warpage were measured using a laser measurement apparatus. The initial printed circuit boards selected displayed bending and warpage of 50±5 μm. The maximum values of bending and warpage were measured using a laser measurement apparatus after connecting the flip chips on.

(2) Cracking and Peeling Defects

For fifty 40×200 mm modules, each having two flip chips of dimensions 10×10 mm and a thickness of 400 μm connected to the left, right, and middle (for a total of six chips) on one or both sides, temperature cycle experiments were performed for a −45° C./30 min←→125° C./30 min cycle for 1000 cycles, and the integrity of the connection was evaluated. Here, a change in resistance value of ±10% or more was classified as a defect. The samples were checked for cracking and peeling in the lead-free solder balls caused by cracking and peeling of the semiconductor chips, and the number of samples free of defects were recorded in Tables 3 and 4.

Comparing Table 3 and Table 4, it can be observed that there were less bending and warpage, as well as fewer cases of cracking and peeling defects, in the multilayered printed circuit boards of the Implementation Examples according to certain embodiments of the invention than in the PCB's of the Comparison Examples. This may be because the metal layers of low coefficient of thermal expansion were stacked on the outermost layers for the multilayered printed circuit boards according to the embodiments of the invention.

Also, as can be seen in Table 3, there are fewer cases of bending and warpage in the overall flip chip package for the cases of mounting semiconductor chips on both sides, compared to the cases of mounting the semiconductor chips on one side only. Furthermore, the higher the remaining percentage of the metal layer in the outermost layers, the fewer the occurrence of bending or warpage in the overall flip chip package.

As set forth above, certain aspects of the invention may provide a multilayered printed circuit board and a method of fabricating the printed circuit board, in which there is high contact reliability between the semiconductor chips and the circuit board.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of fabricating a multilayered printed circuit board, the method comprising:
providing a core substrate having an outer circuit, the core substrate having a thermal expansion coefficient of 10 to 20 ppm/° C. at −60 to 150° C.;
stacking a stress-relieving insulation layer on either side of the core substrate, the stress-relieving insulation layer having a thermal expansion coefficient of −20 to 6 ppm/° C.; and
forming a metal layer on the insulation layer and forming at least one pad by removing at least one portion of the metal layer and electrically connecting the pad with the outer circuit.

2. The method of claim 1, wherein the thermal expansion coefficient of the stress-relieving insulation layer is −15 to 5 ppm/° C.

3. The method of claim 1, wherein the metal layer includes copper.

4. The method of claim 3, wherein a solder resist is filled in between the remaining metal layer and the pad.

5. The method of claim 1, wherein the stress-relieving insulation layer includes a reinforcing material,
the reinforcing material including any one of T(S) glass fiber woven fabric, aromatic polyamide fiber non-woven fabric, aromatic polyamide fiber woven fabric, and liquid crystal polyester resin sheet.

6. The method of claim 5, wherein the stress-relieving insulation layer is a thermosetting resin composition with aromatic polyamide fiber non-woven fabric or aromatic polyamide fiber woven fabric included as the reinforcing material.

7. The method of claim 5, wherein the stress-relieving insulation layer is a thermosetting resin composition with T(S) glass fiber woven fabric included as the reinforcing material.

8. The method of claim 1, wherein the stress-relieving insulation layer is formed from a liquid crystal polyester resin composition having a melting point of 270° C. or higher.

9. The method of claim 1, wherein a solder ball is formed on the pad, the solder ball configured to be connected with a semiconductor chip.

10. A multilayered printed circuit board comprising:
a core substrate having an outer circuit and having a thermal expansion coefficient of 10 to 20 ppm/° C. at −60 to 150° C.;
a stress-relieving insulation layer formed on either side of the core substrate and having a thermal expansion coefficient of −20 to 6 ppm/° C.; and
a pad formed on the stress-relieving insulation layer and electrically connected with the outer circuit.

11. The multilayered printed circuit board of claim 10, wherein the thermal expansion coefficient of the stress-relieving insulation layer is −15 to 5 ppm/° C.

12. The multilayered printed circuit board of claim 10, wherein the metal layer is formed from copper.

13. The multilayered printed circuit board of claim 10, wherein the pad is insulated by a solder resist.

14. The multilayered printed circuit board of claim 10, wherein the stress-relieving insulation layer includes a reinforcing material,
the reinforcing material including any one of T(S) glass fiber woven fabric, aromatic polyamide fiber non-woven fabric, aromatic polyamide fiber woven fabric, and liquid crystal polyester resin sheet.

15. The multilayered printed circuit board of claim 14, wherein the stress-relieving insulation layer is a thermosetting resin composition with aromatic polyamide fiber non-woven fabric or aromatic polyamide fiber woven fabric included as the reinforcing material.

16. The multilayered printed circuit board of claim 14, wherein the stress-relieving insulation layer is a thermosetting resin composition with T(S) glass fiber woven fabric included as the reinforcing material.

17. The multilayered printed circuit board of claim 10, wherein the stress-relieving insulation layer is formed from a liquid crystal polyester resin composition having a melting point of 270° C. or higher.

18. The multilayered printed circuit board of claim 10, wherein a solder ball is formed on the pad, the solder ball configured to be connected with a semiconductor chip.

19. A method of fabricating a multilayered printed circuit board, the method comprising:
providing a core substrate having an outer circuit, the core substrate having a thermal expansion coefficient of 10 to 20 ppm/° C. at −60 to 150° C.;
stacking a metal layer on either side of the core substrate, the metal layer having a thermal expansion coefficient of −5 to 8 ppm/° C.; and
forming at least one pad by removing at least one portion of the metal layer and electrically connecting the pad with the outer circuit of the core substrate.

20. The method of claim 19, wherein the thermal expansion coefficient of the metal layer is −3 to 5 ppm/° C.

21. The method of claim 19, wherein in the removing of the metal layer, a remaining percentage of the metal layer is 50% or higher.

22. The method of claim 21, wherein an insulating material is filled between the remaining metal layer and the pad.

23. The method of claim 19, wherein the metal layer contains Invar.

24. The method of claim 23, wherein a copper foil is attached to the metal layer.

25. The method of claim 24, wherein the metal layer is stacked with an interposed intermediate insulation layer after forming minute roughness on one side of the metal layer.

26. The method of claim 25, wherein a black oxide treatment or a CZ treatment is applied to the copper foil.

27. The method of claim 19, wherein at least one solder ball is formed over the pad, the solder ball connected with a semiconductor chip.

28. A multilayered printed circuit board comprising:
a core substrate having an outer circuit and having a thermal expansion coefficient of 10 to 20 ppm/° C. at −60 to 150° C.;
a metal layer stacked over either side of the core substrate and having a thermal expansion coefficient of −5 to 8 ppm/° C.; and
a pad electrically connected with the outer circuit, the pad formed by removing at least one portion of the metal layer.

29. The multilayered printed circuit board of claim 28, wherein the thermal expansion coefficient of the metal layer is −3 to 5 ppm/° C.

30. The multilayered printed circuit board of claim 28, wherein a remaining percentage of the metal layer is 50% or higher.

31. The multilayered printed circuit board of claim 30, wherein an insulating material is filled between the remaining metal layer and the pad.

32. The multilayered printed circuit board of claim 31, wherein the metal layer contains Invar.

33. The multilayered printed circuit board of claim 32, wherein a copper foil is attached to the metal layer.

34. The multilayered printed circuit board of claim 33, wherein minute roughness is formed on one side of the metal layer.

35. The multilayered printed circuit board of claim 34, wherein minute roughness is formed on the copper foil by a black oxide treatment or a CZ treatment.

36. The multilayered printed circuit board of claim 28, wherein a solder ball is formed over the pad, the solder ball connected with a semiconductor chip.
